(19) United States
(12) Patent Application Publication
(10) Pub. No.: US 2023/0420412 A1
(43) Pub. Date: Dec. 28, 2023

(54) PACKAGING ARCHITECTURE WITH COAXIAL PILLARS FOR HIGH-SPEED INTERCONNECTS

(71) Applicant: Intel Corporation, Santa Clara, CA (US)

(72) Inventors: Hiroki Tanaka, Gilbert, AZ (US); Kristof Kuwawi Darmawikarta, Chandler, AZ (US); Robert Alan May, Chandler, AZ (US); Sri Ranga Sai Boyapati, Austin, TX (US); Srinivas V. Pietambaram, Chandler, AZ (US)

(73) Assignee: Intel Corporation, Santa Clara, CA (US)

(21) Appl. No.: 17/847,434

(22) Filed: Jun. 23, 2022

(51) Int. Cl. H01L 25/065; H01L 23/538; H01L 23/00; H01L 23/31; H01L 23/552

(52) U.S. Cl. CPC H01L 25/0652; H01L 23/5385; H01L 24/16; H01L 23/5384; H01L 23/3121; H01L 23/552; H01L 24/32; H01L 24/73; H01L 24/29; H01L 2224/16225; H01L 2224/32225; H01L 2224/73204; H01L 2224/2929; H01L 2224/29386; H01L 2224/29294; H01L 2224/29293

(57) ABSTRACT

Embodiments of a microelectronic assembly comprise a microelectronic assembly, comprising: a package substrate; an interposer coupled to the package substrate, the interposer comprising a dielectric material, a conductive pillar) through the dielectric material and a conductive structure at least partially surrounding the conductive pillar, the conductive structure separated from the conductive pillar by the dielectric material; and an integrated circuit (IC) die coupled to the interposer on a side opposite to the package substrate. The conductive pillar conductively couples the IC die to the package substrate, and the conductive structure is coupled to a ground connection.

### TECHNICAL FIELD

The present disclosure relates to techniques, methods, and apparatus directed to packaging architecture with coaxial pillars for high-speed interconnects.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2A is a schematic top view of a portion of another example microelectronic assembly according to some embodiments of the present disclosure.

FIG. 2B is a schematic cross-sectional view of the portion shown in FIG. 2A.

FIG. 2C is another schematic cross-sectional view of the portion shown in FIG. 2A.

FIG. 3A is a schematic top view of a portion of yet another example microelectronic assembly according to some embodiments of the present disclosure.

FIG. 3B is a schematic cross-sectional view of the portion shown in FIG. 3A.

FIG. 3C is another schematic cross-sectional view of the portion shown in FIG. 3A.

FIG. 4A is a schematic top view of a portion of yet another example microelectronic assembly according to some embodiments of the present disclosure.

FIG. 4B is a schematic cross-sectional view of the portion shown in FIG. 4A.

FIG. 4C is another schematic cross-sectional view of the portion shown in FIG. 4A.

FIG. 5A is a schematic top view of a portion of yet another example microelectronic assembly according to some embodiments of the present disclosure.

FIG. 5B is a schematic cross-sectional view of the portion shown in FIG. 5A.

FIG. 5C is another schematic cross-sectional view of the portion shown in FIG. 5A.

FIG. 6 is a schematic cross-sectional view of a portion of an example microelectronic assembly according to some embodiments of the present disclosure.

FIG. 7 is a schematic cross-sectional view of a portion of another example microelectronic assembly according to some embodiments of the present disclosure.

FIG. 8A is a schematic top view of a portion of yet another example microelectronic assembly according to some embodiments of the present disclosure.

FIG. 8B is a schematic cross-sectional view of the portion shown in FIG. 8A.

FIG. 8C is another schematic cross-sectional view of the portion shown in FIG. 8A.

FIG. 8D is another schematic cross-sectional view of the portion shown in FIG. 8A according to another embodiment of the present disclosure.

FIG. 9A is a schematic top view of a portion of yet another example microelectronic assembly according to some embodiments of the present disclosure.

FIG. 9B is a schematic cross-sectional view of the portion shown in FIG. 9A.

FIG. 9C is another schematic cross-sectional view of the portion shown in FIG. 9A.

FIG. 10 is a schematic flow-diagram illustrating example operations that may be associated with an example microelectronic assembly according to some embodiments of the present disclosure.

FIG. 11 is a cross-sectional view of a device package that includes one or more microelectronic assemblies in accordance with any of the embodiments disclosed herein.

FIG. 12 is a cross-sectional side view of a device assembly that includes one or more microelectronic assemblies in accordance with any of the embodiments disclosed herein.

FIG. 13 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Many computing schemes such as artificial intelligence, machine learning and other emerging applications require more computing horsepower with higher performance, extremely low latency, and smaller form factors than traditional computing applications. Such demands foster the development of a 3-dimensional multi-chip package (3-D MCP) technology. Conventionally, 3-D MCP is achieved by utilizing through-silicon vias (TSV) to stack IC dies serving different functionalities such as application specific integrated circuits (ASIC), radio frequency (RF) circuits, and memory circuits in a single package, for example, to achieve higher aggregated data bandwidth, low latency, less interconnect loss, and hence less power consumption.

While TSVs offer a short interconnection among dies in a single MCP, it inherently experiences certain detriments such as reflection due to the impedance mismatch at the interfaces between two stacked dies. Moreover, multiple reflections can occur along such short vertical interconnects, which further amplify the impairments caused by the reflection. TSVs also suffer from crosstalk, particularly for high-speed signals (e.g., with speeds greater than 10 GHz). Given that TSV is fabricated as vertical interconnect in silicon with a high dielectric constant, small diameter, and very confined pitch, the crosstalk, particularly near end crosstalk is expected to be high even when the interconnect length is relative short. TSVs also have increased latency. Due to thin oxide liners in IC dies, the electrical field generated by the TSVs infringes on the performance of active devices in silicon, resulting in larger TSV capacitance, and hence a latency increase. Devices also suffer from lower resonant frequency from the presence of TSVs. Since the TSV capacitance is larger and it is an inductive vertical interconnect by nature, the resonant frequency of the TSV is usually low. The low resonant frequency limits the data rate of the die-to-die input/output speeds. Common practices to improve the performance of TSVs include employing more ground TSVs and properly arranging them, enlarging the pitches, and increasing TSV oxide liner thickness, etc.

Together with TSVs, through-mold vias (TMVs) are another packaging feature of complex devices. Advances in semiconductor processing and logic design have permitted an increase in the amount of logic circuits that may be included in processors and other IC devices. By stacking IC dies one on top of another in a true 3D packaging architecture, reduction in form factor without sacrificing speeds may be achieved. In one example packaging architecture, a pair of IC dies are coupled face-to-face by high-density interconnects, at least one IC die in the pair being encased in a mold compound to form an interposer between the other IC die in the pair and the package substrate, with TMVs made of copper providing electrical coupling through the interposer between the package substrate on one side of the interposer and the IC die on an opposite side of the interposer.

However, in addition to the same or similar detriments as with TSVs, such packaging architecture with TMVs have problems relating to plating uniformity, electrical performance, and dielectric adhesion during manufacture. Because the TMVs tend to be arranged densely closer to the periphery of the interposer than in the middle, the non-uniform arrangement and low copper density in the medial region of the interposer can affect the plating process. For example, the non-uniform copper density renders it difficult to control copper plating uniformity, which can affect planarization and via reveal processes also. Adhesion between layers is also poor due to this non-uniform copper density. In addition, TMVs are individual, unshielded pillars through the mold compound, and as such, cannot efficiently conduct high-speed electrical signals. For example, such unshielded TMVs can present appreciable loss from crosstalk between adjacent TMVs.

Accordingly, embodiments of a microelectronic assembly disclosed herein comprise a microelectronic assembly, comprising: a package substrate; an interposer coupled to the package substrate, the interposer comprising a dielectric material, a conductive pillar) through the dielectric material and a conductive structure at least partially surrounding the conductive pillar, the conductive structure separated from the conductive pillar by the dielectric material; and an IC die coupled to the interposer on a side opposite to the package substrate. The conductive pillar conductively couples the IC die to the package substrate, and the conductive structure is coupled to a ground connection. In various embodiments, the conductive structure comprises an electromagnetic shield

In various embodiments, the conductive pillars and the electromagnetic shield with the dielectric material separating them form coaxial pillar structures, which can provide better electrical performance than unshielded TMVs for high-speed signaling. In addition, because the electromagnetic shield may have greater volume and may be spread over a larger area than unshielded TMVs, copper density is higher than with unshielded TMVs, leading to better plating uniformity, better electrical performance and better adhesion between layers in the interposer. In various embodiments, the traditional process used for fabricating interposers with TMVs may be modified by changing the mask designs used in the photolithography process to include the electromagnetic shield separated from the conductive pillar by the dielectric material. In some embodiments, full shielding may be implemented, with the electromagnetic shield surrounding each conductive pillar separately; in other embodiments, partial shielding may be implemented, with the electromagnetic shield surrounding groups of adjacent conductive pillars, for example, arranged in an n×n array of conductive pillars or as horizontal or vertical slots of ground shielding between n×n array of conductive pillars. Such partial shielding configuration may be used in scenarios where the pillar-to-pillar pitch is too narrow (e.g., less than 30 micrometers) as to fall outside the resist resolution. The dielectric material used in the interposer may comprise mold compound, and/or may comprise porous or hollow silica fillers, fluorinated silica fillers, and polymers such as cyclotenes, benzocyclobutenes, paraffins and perfluoroalkyls.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group Ill-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

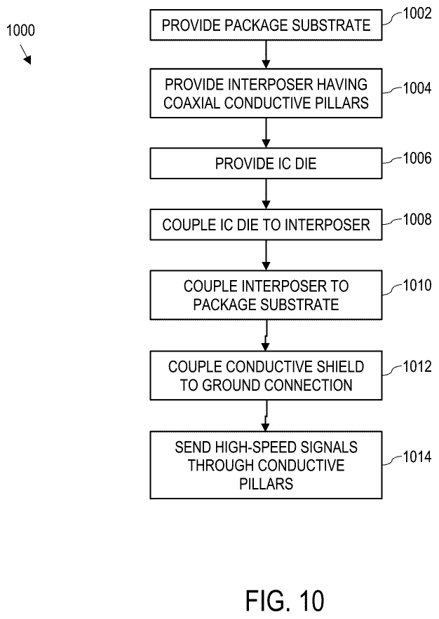

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

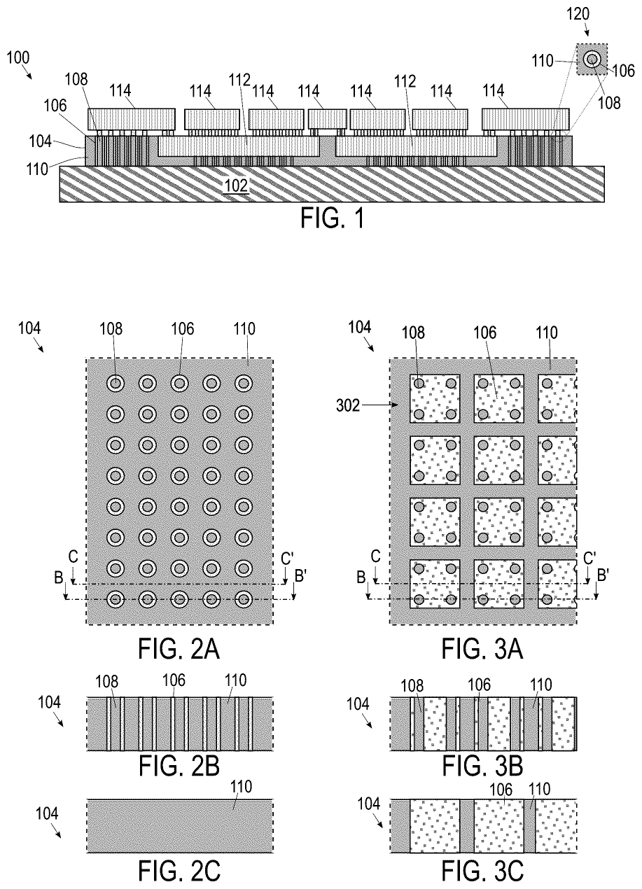

FIG. 1 is a schematic cross-sectional view of an example microelectronic assembly 100 according to some embodiments of the present disclosure. Microelectronic assembly 100 comprises, in the embodiment shown, a package substrate 102 coupled to an interposer 104. Interposer 104 comprises a dielectric material 106, conductive pillars 108 through dielectric material 106, and an electromagnetic shield 110 at least partially surrounding conductive pillars 108. In various embodiments, electromagnetic shield 110 is a conductive structure. Electromagnetic shield 110 is separated from conductive pillars 108 by dielectric material 106. In some embodiments, interposer 104 may comprise one or more IC dies 112 embedded therein. Dielectric material 106 may surround IC die 112 on sides of IC dies 112 orthogonal to the sides of IC dies 112 facing IC dies 114. Other IC dies 114 may be coupled to interposer 104 on a side of interposer 104 opposite to package substrate 102. Conductive pillars 108 conductively couple IC dies 114 (and/or 112) to package substrate 102, and electromagnetic shield 110 is coupled to a ground connection (not shown).

In some embodiments, for example, as shown by the top view of portion 120 in inset, each one of conductive pillars 108 has a circular cross-section, and dielectric material 106 surrounding each conductive pillar 108 has a circular periphery. In other words, dielectric material 106 forms hollow cylindrical rings in electromagnetic shield 110, each conductive pillar 108 being within a respective ring; i.e., dielectric material 106 may conformally envelop each conductive pillar 108, which may be in the shape of a cylinder with a diameter between 60 micrometers and 70 micrometers in various embodiments. Various other configurations and shapes (e.g., rectangular cross-section, octagonal cross-section, etc.) are also possible, a selection of which are as described in regards to other figures. The material of conductive pillars 108 may be the same as electromagnetic shield 110, for example, copper, in some embodiments. In other embodiments, conductive pillars 108 and electromagnetic shield 110 may comprise different materials. In various embodiments, some conductive pillars 108 are configured to provide conductive pathways for high-speed electrical signals, some other conductive pillars 108 may conduct power, and yet other conductive pillars 108 may be coupled to ground.

In various embodiments, electromagnetic shield 110 extends through interposer 104 between the side of interposer 104 proximate and adjacent to package substrate 102, and the opposite side of interposer 104 proximate and adjacent to IC dies 114. In some embodiments, conductive pillars 108 may also be disposed in interposer 104 between IC dies 112 and package substrate 102. Such conductive pillars 108 may conductively couple IC dies 112 to package substrate 102. As with other conductive pillars 108 coupling IC dies 114 and package substrate 102, dielectric material 106 surrounds conductive pillars 108 between IC dies 112 and package substrate 102. Electromagnetic shield 110 at least partially surrounds conductive pillars 108 between IC dies 112 and package substrate 102. Electromagnetic shield 110 is separated from conductive pillars 108 between IC dies 112 and package substrate 102 by dielectric material 106.

In various embodiments, dielectric material 106 comprises an organic dielectric material having a dielectric constant between 2 and 4 and a dissipation factor (e.g., loss tangent) between 0.002 and 0.005. In some embodiments, dielectric material 106 comprises mold compound. In some embodiments, dielectric material 106 comprises at least one of: epoxy with porous silica fillers, epoxy with fluorinated silica fillers, cyclotene, henzocyclobutene, paraffin, and perfluoroalkyl.

FIG. 2A is a schematic top view of a portion of another example microelectronic assembly 100 according to some embodiments of the present disclosure. In some embodiments, each one of conductive pillars 108 has a circular cross-section, and dielectric material 106 conformally surrounding each conductive pillar 108 has a circular periphery. In the example embodiment shown, dielectric material 106 around each conductive pillar 108 is completely surrounded by electromagnetic shield 110.

FIG. 2B is a schematic cross-sectional view of the portion shown in FIG. 2A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown).

FIG. 2C is another schematic cross-sectional view of the portion shown in FIG. 2A, the cross-section being along axis CC′. As can be seen from the figure, electromagnetic shield 110 extends through the cross-section continuously, unbroken by dielectric material, and provides electromagnetic shielding to conductive pillars 108. Thus, in the embodiment shown in the figures, interposer 104 substantially comprises the conductive material of electromagnetic shield 110 and conductive pillars 108, with hollow cylindrical rings of dielectric material 118 distributed therethrough according to particular needs.

FIG. 3A is a schematic top view of a portion of yet another example microelectronic assembly 100 according to some embodiments of the present disclosure. In some embodiments, dielectric material 106 may surround separate subsets of mutually adjacent conductive pillars 108, and dielectric material 106 may be completely surrounded by electromagnetic shield 110. In the example embodiment shown in the figure, mutually adjacent conductive pillars 108 in each subset form a 2×2 array 302 of conductive pillars 108. Each conductive pillar 108 in each subset is thus partially shielded by electromagnetic shield 110. For example, conductive pillars 108 in each array 302 may not be shielded from each other; conductive pillars 108 in different (e.g., adjacent) arrays 302 may be shielded by electromagnetic shield 110. Such partial shielding configuration may be used in scenarios where the pillar-to-pillar pitch is too narrow (e.g., less than 30 micrometers) as to fall outside the photoresist resolution during fabrication.

FIG. 3B is a schematic cross-sectional view of the portion shown in FIG. 3A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown). In the example embodiment shown, dielectric material 106 may be wider in a medial region of array 302 compared to a peripheral region of array 302.

FIG. 3C is another schematic cross-sectional view of the portion shown in FIG. 3A, the cross-section being along axis CC′. As can be seen from the figure, electromagnetic shield 110 may be arranged as a grid of slots extending through the thickness of interposer 104 between a side adjacent to package substrate 102 (not shown) and an opposite side adjacent to IC dies 114 (not shown), with dielectric material 106 within the grid.

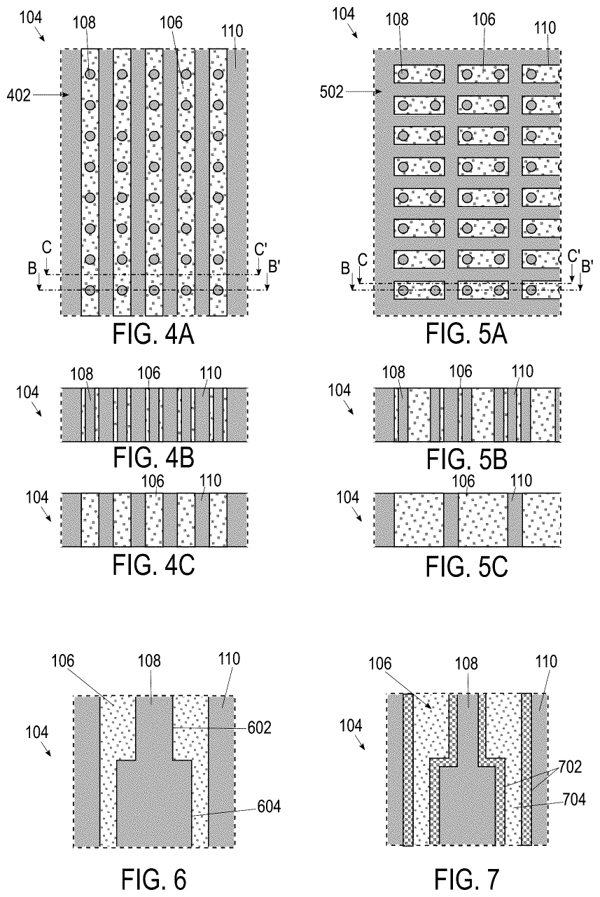

FIG. 4A is a schematic top view of a portion of yet another example microelectronic assembly 100 according to some embodiments of the present disclosure. In some embodiments, dielectric material 106 may surround separate subsets of mutually adjacent conductive pillars 108, and dielectric material 106 may be completely surrounded by electromagnetic shield 110. In the example embodiment shown in the figure, mutually adjacent conductive pillars 108 in each subset form a row 402 of conductive pillars 108. Row 402 may extend across a length or width of interposer 104.

FIG. 4B is a schematic cross-sectional view of the portion shown in FIG. 4A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown).

FIG. 4C is another schematic cross-sectional view of the portion shown in FIG. 4A, the cross-section being along axis CC′. As can be seen from the figure, electromagnetic shield 110 may be arranged as rows of slots extending through the thickness of interposer 104 between a side adjacent to package substrate 102 (not shown) and an opposite side adjacent to IC dies 114 (not shown), with dielectric material 106 between the rows.

FIG. 5A is a schematic top view of a portion of yet another example microelectronic assembly 100 according to some embodiments of the present disclosure. In some embodiments, dielectric material 106 may surround separate subsets of mutually adjacent conductive pillars 108, and dielectric material 106 may be completely surrounded by electromagnetic shield 110. In the example embodiment shown in the figure, mutually adjacent conductive pillars 108 in each subset form a pair 502 of conductive pillars 108.

FIG. 5B is a schematic cross-sectional view of the portion shown in FIG. 5A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown). In the example embodiment shown, dielectric material 106 may be wider in a medial region of pair 502 compared to a peripheral region of pair 502.

FIG. 5C is another schematic cross-sectional view of the portion shown in FIG. 5A, the cross-section being along axis CC′. As can be seen from the figure, electromagnetic shield 110 may be arranged as a grid of slots extending through the thickness of interposer 104 between a side adjacent to package substrate 102 (not shown) and an opposite side adjacent to IC dies 114 (not shown), with dielectric material 106 within the grid.

FIG. 6 is a schematic cross-sectional view of a portion of an example microelectronic assembly 100 according to some embodiments of the present disclosure. In various embodiments, each conductive pillar 108 may comprises multiple portions, for example, each portion fabricated in a separate electroplating process. In the embodiment shown in the figure, conductive pillar 108 comprises a first portion 602 and a second portion 604. First portion 602 has a different (e.g., smaller) diameter than second portion 604. Various other such configurations may be included in the broad scope of the embodiments.

FIG. 7 is a schematic cross-sectional view of a portion of another example microelectronic assembly 100 according to some embodiments of the present disclosure. In some embodiments, dielectric material 106 comprises a first dielectric material 702 and a second dielectric material 704. First dielectric material 702 may form a conformal layer of passivation coating around conductive pillar 108, separating conductive pillar 108 from second dielectric material 704. Likewise, in some embodiments, first dielectric material 702 may form a conformal layer of passivation coating over electromagnetic shield 110 in the vicinity of dielectric material 704, separating electromagnetic shield 110 from dielectric material 704. In various embodiments, second dielectric material 704 may comprise organic dielectric materials discussed in relation to previous figures, for example, mold compound and epoxy with different kinds of silica fillers. In some embodiments, first dielectric material 702 comprises silicon nitride having a thickness of 0.5 micrometer or less.

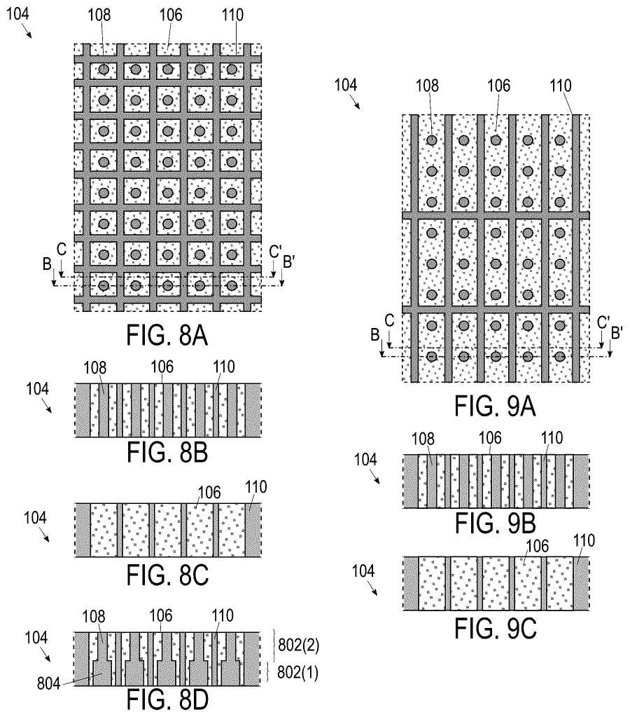

FIG. 8A is a schematic top view of a portion of yet another example microelectronic assembly 100 according to some embodiments of the present disclosure. In the example embodiment shown, each conductive pillar 108 has a circular cross-section, and dielectric material 106 surrounding each conductive pillar 108 has a rectangular periphery. In other words, electromagnetic shield 110 comprises a grid of slots in dielectric material 106 between conductive pillars 108.

FIG. 8B is a schematic cross-sectional view of the portion shown in FIG. 8A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown).

FIG. 8C is another schematic cross-sectional view of the portion shown in FIG. 8A, the cross-section being along axis CC′. As can be seen from the figure, electromagnetic shield 110 may be arranged as a grid of slots extending through the thickness of interposer 104 between a side adjacent to package substrate 102 (not shown) and an opposite side adjacent to IC dies 114 (not shown), with dielectric material 106 within the grid.

FIG. 8D is another schematic cross-sectional view of the portion shown in FIG. 8A according to another embodiment of the present disclosure, the cross-section being along axis BB′. In the example embodiment shown, interposer 104 may comprise multiple layers 802, with conductive pillar 108, dielectric material 106 and electromagnetic shield 110 in each layer 802 having different dimensions than in other layers 802. For example, layer 802(1) may be adjacent to package substrate 102 and may comprise landing pads 804 having larger diameters than respected conductive pillars 108 attached thereto. Electromagnetic shield 110 may have uniform width through both layers 802 in the example embodiment shown. In other embodiments, electromagnetic shield 110 may also have differing dimensions in different layers 802.

FIG. 9A is a schematic top view of a portion of yet another example microelectronic assembly 100 according to some embodiments of the present disclosure. In some embodiments, dielectric material 106 may surround separate subsets of mutually adjacent conductive pillars 108, and dielectric material 106 may be completely surrounded by electromagnetic shield 110. In the example embodiment shown in the figure, mutually adjacent conductive pillars 108 in each subset form a 1×3 array 302 of conductive pillars 108.

FIG. 9B is a schematic cross-sectional view of the portion shown in FIG. 8A, the cross-section being along axis BB′. As can be seen from the figure, dielectric material 106, conductive pillars 108, and electromagnetic shield 110 extend through a thickness of interposer 104 between a side adjacent to package substrate 102 (not shown) and an opposite side adjacent to IC dies 114 (not shown).

FIG. 9C is another schematic cross-sectional view of the portion shown in FIG. 8A, the cross-section being along axis CC′. As can be seen from the figure, electromagnetic shield 110 may be arranged as a grid of slots extending through the thickness of interposer 104 between a side adjacent to package substrate 102 (not shown) and an opposite side adjacent to IC dies 114 (not shown), with dielectric material 106 within the grid.

In various embodiments, any of the features discussed with reference to any of FIGS. 1-9 herein may be combined with any other features to form a package with one or more IC dies as described herein, for example, to form a modified microelectronic assembly 100. Some such combinations are described above, but, in various embodiments, further combinations and modifications are possible.

### Example Methods

FIG. 10 is a schematic flow-chart of various operations 1000 associated with an example microelectronic assembly 100 according to some embodiments of the present disclosure. At 1002, package substrate 102 may be provided. At 1004, interposer 104 may be provided, interposer 104 comprising dielectric material 106, conductive pillars 108, and electromagnetic shield 110. Conductive pillars 108 are surrounded by dielectric material 106, and dielectric material 106 is surrounded by electromagnetic shield 110. In some embodiments, interposer 104 may further comprise IC dies 112. At 1006, IC dies 114 may be provided. At 1008, IC dies 114 may be coupled to interposer 104, for example, using appropriate DTD interconnects as described in a previous sub-section. At 1010, interposer 104 may be coupled to package substrate 102. Conductive pillars 108 extend through interposer 104, providing a conductive pathway between IC dies 114 and package substrate 102. At 1012, electromagnetic shield 110 may be coupled to a ground connection. At 1014, high-speed signals having a frequency greater than 10 GHz may be conducted (e.g., transmitted, received, etc.) through conductive pillars 108. Electromagnetic shield 110 shields conductive pillars 108, enabling high-speed signals to be transmitted (or received) without significant loss.

Although FIG. 10 illustrates various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIG. 10 may be modified in accordance with the present disclosure to fabricate others of microelectronic package 100 disclosed herein. Although various operations are illustrated in FIG. 10 once each, the operations may be repeated as often as desired. For example, one or more operations may be performed in parallel to manufacture and test multiple microelectronic packages substantially simultaneously. In another example, the operations may be performed in a different order to reflect the structure of a particular microelectronic package in which one or more substrates or other components as described herein may be included.

Furthermore, the operations illustrated in FIG. 10 may be combined or may include more details than described. Still further, the various operations shown and described may further include other manufacturing operations related to fabrication of other components of the microelectronic assemblies described herein, or any devices that may include the microelectronic assemblies as described herein. For example, the operations not shown in FIG. 10 may include various cleaning operations, additional surface planarization operations, operations for surface roughening, operations to include barrier and/or adhesion layers as desired, and/or operations for incorporating microelectronic packages as described herein in, or with, an IC component, a computing device, or any desired structure or device.

### Example Devices and Components

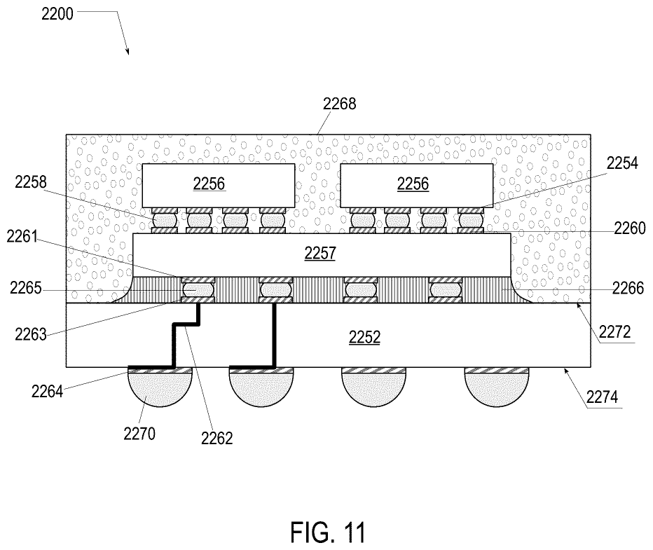

The packages disclosed herein, e.g., any of the embodiments shown in FIGS. 1-10 or any further embodiments described herein, may be included in any suitable electronic component. FIGS. 11-13 illustrate various examples of packages, assemblies, and devices that may be used with or include any of the IC packages as disclosed herein.

FIG. 11 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

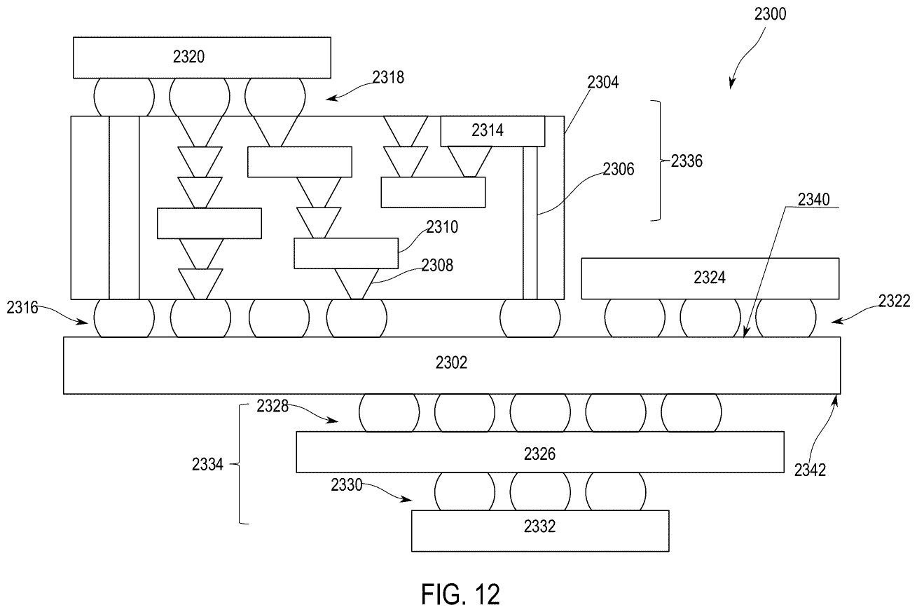

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 12.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 12 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 8. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group Ill-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as RF devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

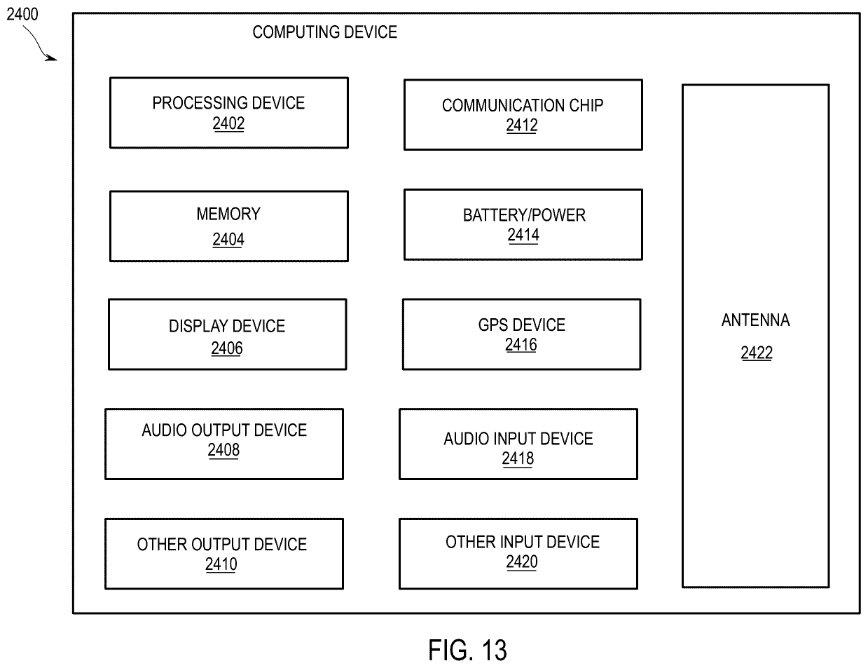

FIG. 13 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 8). In yet another example, any one or more of the components of computing device 2400 may include an IC device assembly 2300 (e.g., as shown in FIG. 12).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### SELECT EXAMPLES

The following paragraphs provide various examples of the embodiments disclosed herein.

Example 1 provides a microelectronic assembly (e.g., 100), comprising: a package substrate (e.g., 102); an interposer (e.g., 104) coupled to the package substrate, the interposer comprising a dielectric material (e.g., 106), a conductive pillar (e.g., 108) through the dielectric material and a conductive structure (e.g., 110) at least partially surrounding the conductive pillar, the conductive structure separated from the conductive pillar by the dielectric material; and an integrated circuit (IC) die (e.g., 114) coupled to the interposer on a side opposite to the package substrate, in which: the conductive pillar couples the IC die conductively to the package substrate, and the conductive structure is coupled to a ground connection.

Example 2 provides the microelectronic assembly of example 1, in which: the conductive pillar has a circular cross-section, and the dielectric material surrounding the conductive pillar has a circular periphery.

Example 3 provides the microelectronic assembly of example 1, in which (e.g., FIG. 8): the conductive pillar has a circular cross-section, and the dielectric material surrounding the conductive pillar has a rectangular periphery.

Example 4 provides the microelectronic assembly of any one of examples 1-3, further comprising a plurality of conductive pillars.

Example 5 provides the microelectronic assembly of example 4, in which (e.g., FIG. 2) the dielectric material around each conductive pillar is completely surrounded by the conductive structure.

Example 6 provides the microelectronic assembly of example 4, in which (e.g., FIGS. 3-5): the dielectric material around a subset of the conductive pillars is completely surrounded by the conductive structure, and the subset comprises a plurality of mutually adjacent conductive pillars.

Example 7 provides the microelectronic assembly of example 6, in which (e.g., FIG. 3) the plurality of mutually adjacent conductive pillars is in an array (e.g., 302) of the conductive pillars.

Example 8 provides the microelectronic assembly of example 6, in which (e.g., FIG. 4) the plurality of mutually adjacent conductive pillars is in a row (e.g., 402) of the conductive pillars.

Example 9 provides the microelectronic assembly of example 8, in which the row extends across a length or width of the interposer.

Example 10 provides the microelectronic assembly of example 6, in which (e.g., FIG. 5) the plurality of mutually adjacent conductive pillars is a pair (e.g., 502) of the conductive pillars.

Example 11 provides the microelectronic assembly of any one of examples 1-10, in which (e.g., FIG. 6) the conductive pillar comprises a first portion (e.g., 602) and a second portion (e.g., 604), the first portion having a different diameter than the second portion.

Example 12 provides the microelectronic assembly of any one of examples 1-11, in which (e.g., FIG. 7) the dielectric material comprises: a first dielectric material (e.g., 702) and a second dielectric material (e.g., 704), and the first dielectric material separates the conductive pillar from the second dielectric material.

Example 13 provides the microelectronic assembly of example 12, in which the first dielectric material is a passivation layer comprising silicon and nitrogen.

Example 14 provides the microelectronic assembly of any one of examples 1-13, in which (e.g., FIG. 1): the conductive structure extends through the interposer between a first side of the interposer and a second side of the interposer, the first side is adjacent to the package substrate, and the second side is adjacent to the IC die.

Example 15 provides the microelectronic assembly of any one of examples 1-14, in which (e.g., FIG. 8) the conductive structure comprises a grid of slots in the dielectric material between the conductive pillars.

Example 16 provides the microelectronic assembly of any one of examples 1-15, in which (e.g., FIG. 1) the IC die comprises a first IC die and the interposer further comprises a second IC die (e.g., 112) surrounded by the dielectric material.

Example 17 provides the microelectronic assembly of example 16, in which: the conductive pillar is a first conductive pillar, the interposer further comprises a second conductive pillar between the second IC die and the package substrate, the second conductive pillar couples the second IC die conductively to the package substrate, the dielectric material surrounds the second conductive pillar, the conductive structure at least partially surrounds the second conductive pillar, and the conductive structure is separated from the second conductive pillar by the dielectric material.

Example 18 provides the microelectronic assembly of any one of examples 1-17, in which the dielectric material has a dielectric constant between 2 and 4 and a dissipation factor between 0.002 and 0.005.

Example 19 provides the microelectronic assembly of any one of examples 1-18, in which the conductive structure comprises an electromagnetic shield.

Example 20 provides the microelectronic assembly of any one of examples 1-19, in which the conductive pillar is configured to provide a conductive pathway for at least one of: signals, power, and ground.

Example 21 provides an IC package (e.g., 100), comprising: a package substrate (e.g., 102); an interposer (e.g., 104) coupled to the package substrate, the interposer comprising: a first IC die (e.g., 112); a dielectric material (e.g., 106); a first plurality of conductive pillars (e.g., 108) through the dielectric material, the first plurality of conductive pillars between the first IC die and the package substrate; a second plurality of conductive pillars through the dielectric material; and an electromagnetic shield (e.g., 110) at least partially surrounding the conductive pillars of the first plurality of conductive pillars and the second plurality of conductive pillars, the electromagnetic shield separated from the conductive pillars by the dielectric material; and a second IC die (e.g., 114) coupled to the interposer on a side opposite to the package substrate, in which: the electromagnetic shield is a conductive structure, the first plurality of conductive pillars conductively couples the first IC die and the package substrate, and the second plurality of conductive pillars conductively couples the second IC die and the package substrate.

Example 22 provides the IC package of example 21, in which the electromagnetic shield extends between a first side of the interposer adjacent to the package substrate and a second side of the interposer adjacent to the second IC die.

Example 23 provides the IC package of example 21, in which the conductive pillars are cylindrical.

Example 24 provides the IC package of example 23, in which the dielectric material conformally envelops each conductive pillar.

Example 25 provides the IC package of example 21, in which: subsets of the conductive pillars in at least one of the first plurality of conductive pillars and the second plurality of conductive pillars are in respective blocks of the dielectric material, each subset comprises a plurality of mutually adjacent conductive pillars, and the electromagnetic shield separates the respective blocks of the dielectric material.

Example 26 provides the IC package of example 25, in which each subset comprises a two-dimensional array of the conductive pillars.

Example 27 provides the IC package of example 25, in which each subset comprises a one-dimensional array of the conductive pillars.

Example 28 provides the IC package of any one of examples 21-27, in which the electromagnetic shield is conductively coupled to a ground connection.

Example 29 provides the IC package of any one of examples 21-28, in which the dielectric material comprises at least one of: epoxy with porous silica fillers, epoxy with fluorinated silica fillers, cyclotene, henzocyclobutene, paraffin, and perfluoroalkyl.

Example 30 provides the IC package of any one of examples 21-29, in which the conductive pillars have diameters between 60 micrometers and 70 micrometers.

Example 31 provides a method (e.g., 1000) for fabricating a microelectronic assembly, the method comprising (e.g., FIG. 8): providing a package substrate (e.g., 1002); providing an interposer comprising conductive pillars, a dielectric material and an electromagnetic shield (e.g., 1004); providing an IC die (e.g., 1006); coupling the IC die to the interposer (e.g., 1008); and coupling the interposer to the package substrate (e.g., 1010), in which: the conductive pillars extend through the interposer providing a conductive pathway between the IC die and the package substrate, the conductive pillars are surrounded by the dielectric material, and the dielectric material is surrounded by the electromagnetic shield.

Example 32 provides the method of example 31, further comprising coupling the electromagnetic shield to a ground connection (e.g., 1012).

Example 33 provides the method of any one of examples 31-32, further comprising sending high-speed signals having a frequency greater than 10 GHz through the conductive pillars (e.g., 1014).

Example 34 provides the method of any one of examples 31-33, in which each conductive pillar is surrounded by the dielectric material.

Example 35 provides the method of any one of examples 31-33, in which: different pluralities of the conductive pillars are surrounded by respective blocks of the dielectric material, and the respective blocks of the dielectric material are separated by the electromagnetic shield.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a package substrate;
an interposer coupled to the package substrate, the interposer comprising a dielectric material, a conductive pillar through the dielectric material and a conductive structure at least partially surrounding the conductive pillar, the conductive structure separated from the conductive pillar by the dielectric material; and
an integrated circuit (IC) die coupled to the interposer on a side opposite to the package substrate,
wherein:
the conductive pillar couples the IC die conductively to the package substrate, and
the conductive structure is coupled to a ground connection.

2. The microelectronic assembly of claim 1, further comprising a plurality of conductive pillars.

3. The microelectronic assembly of claim 2, wherein the dielectric material around each conductive pillar is completely surrounded by the conductive structure.

4. The microelectronic assembly of claim 2, wherein:
the dielectric material around a subset of the conductive pillars is completely surrounded by the conductive structure, and
the subset comprises a plurality of mutually adjacent conductive pillars.

5. The microelectronic assembly of claim 4, wherein the plurality of mutually adjacent conductive pillars is in an array of the conductive pillars.

6. The microelectronic assembly of claim 4, wherein the plurality of mutually adjacent conductive pillars is in a row of the conductive pillars.

7. The microelectronic assembly of claim 1, wherein the dielectric material comprises:
a first dielectric material and a second dielectric material, and
the first dielectric material separates the conductive pillar from the second dielectric material.

8. The microelectronic assembly of claim 1, wherein:
the conductive structure extends through the interposer between a first side of the interposer and a second side of the interposer,
the first side is adjacent to the package substrate, and
the second side is adjacent to the IC die.

9. The microelectronic assembly of claim 1, wherein:
the IC die comprises a first IC die,
the interposer further comprises a second IC die surrounded by the dielectric material the conductive pillar is a first conductive pillar,
the interposer further comprises a second conductive pillar between the second IC die and the package substrate,
the second conductive pillar couples the second IC die conductively to the package substrate,
the dielectric material surrounds the second conductive pillar,
the conductive structure at least partially surrounds the second conductive pillar, and
the conductive structure is separated from the second conductive pillar by the dielectric material.

10. The microelectronic assembly of claim 1, wherein the conductive structure comprises an electromagnetic shield.

11. An IC package, comprising:
a package substrate;
an interposer coupled to the package substrate, the interposer comprising:
a first IC die;
a dielectric material;
a first plurality of conductive pillars through the dielectric material, the first plurality of conductive pillars between the first IC die and the package substrate;
a second plurality of conductive pillars through the dielectric material; and
an electromagnetic shield at least partially surrounding the conductive pillars of the first plurality of conductive pillars and the second plurality of conductive pillars, the electromagnetic shield separated from the conductive pillars by the dielectric material; and
a second IC die coupled to the interposer on a side opposite to the package substrate,
wherein:
the electromagnetic shield is a conductive structure,
the first plurality of conductive pillars conductively couples the first IC die and the package substrate, and
the second plurality of conductive pillars conductively couples the second IC die and the package substrate.

12. The IC package of claim 11, wherein the electromagnetic shield extends between a first side of the interposer adjacent to the package substrate and a second side of the interposer adjacent to the second IC die.

13. The IC package of claim 11, wherein:
subsets of the conductive pillars in at least one of the first plurality of conductive pillars and the second plurality of conductive pillars are in respective blocks of the dielectric material,
each subset comprises a plurality of mutually adjacent conductive pillars, and
the electromagnetic shield separates the respective blocks of the dielectric material.

14. The IC package of claim 13, wherein each subset comprises a two-dimensional array of the conductive pillars.

15. The IC package of claim 13, wherein each subset comprises a one-dimensional array of the conductive pillars.

16. The IC package of claim 11, wherein the electromagnetic shield is conductively coupled to a ground connection.

17. The IC package of claim 11, wherein the dielectric material comprises at least one of: epoxy with porous silica fillers, epoxy with fluorinated silica fillers, cyclotene, henzocyclobutene, paraffin, and perfluoroalkyl.

18. A method for fabricating a microelectronic assembly, the method comprising:
providing a package substrate;
providing an interposer comprising conductive pillars, a dielectric material and an electromagnetic shield;
providing an IC die;
coupling the IC die to the interposer; and
coupling the interposer to the package substrate,
wherein:
the conductive pillars extend through the interposer providing a conductive pathway between the IC die and the package substrate,
the conductive pillars are surrounded by the dielectric material, and
the dielectric material is surrounded by the electromagnetic shield.

19. The method of claim 18, further comprising coupling the electromagnetic shield to a ground connection.

20. The method of claim 18, further comprising sending high-speed signals having a frequency greater than 10 GHz through the conductive pillars.
